(19) United States
(12) Patent Application Publication
(10) Pub. No.: US 2013/0107477 A1
(43) Pub. Date: May 2, 2013

(54) ELECTRONIC APPARATUS AND OBLIQUELY FASTENED CIRCUIT BOARD MODULE

(71) Applicants: Hung-Chi CHEN, Taipei City (TW); Chia-Te Tsao, Taipei City (TW); Chong-Kuo Lai, Taipei City (TW)

(72) Inventors: Hung-Chi CHEN, Taipei City (TW); Chia-Te Tsao, Taipei City (TW); Chong-Kuo Lai, Taipei City (TW)

(21) Appl. No.: 13/422,817

(22) Filed: Mar. 16, 2012

(30) Foreign Application Priority Data
Oct. 26, 2011 (TW) 100138876

(51) Int. Cl. H05K 5/03

(52) U.S. Cl. 361/752

(57) ABSTRACT

An electronic apparatus includes an upper cover, a lower cover, a circuit board, and a bracket. The upper cover includes a first boss. The lower cover includes a second boss. The bracket includes a first fixing plate and a second fixing plate that are connected to each other. The first fixing plate is clamped between the first boss and the second boss. The second fixing plate tilts at an angle relative to the first fixing plate. The circuit board and the second fixing plate are fixed to each other in a parallel manner.

### RELATED APPLICATIONS

This application claims priority to Taiwan Application Serial Number 100138876, filed Oct. 26, 2011, which is herein incorporated by reference.

### BACKGROUND

1. Field of Invention

The present invention relates to an electronic apparatus and a circuit board module thereof, and more particularly, to an electronic apparatus and a circuit board thereof, in which the circuit board module is obliquely disposed in the electronic apparatus.

2. Description of Related Art

Motors are used in a wide range of applications. For example, lathes, drills, saws, etc. used in various kinds of industries include motors, and tape recorders, CD-ROM (compact disc read-only memory) drives, hard drives, pumps, hair dryers, vacuum cleaners, refrigerators, air-conditioning compressors, fans, etc. used in daily life cannot operate without motors. In today's information age, the dependence of people on electronic products is increasing. With the ability to offer the features of high-speed, high-performance, and full mobility by today's electronic products, various kinds of portable electronic devices have become ubiquitous. For example, portable electronic devices such as notebook computers, mobile phones, and personal digital assistants have become indispensable application tools of modern life and work.

In the case of a notebook computer, the housing thereof is designed in a compact manner to ensure a lightweight structure and enhance portability. For many users, the front edge of the housing of the notebook computer has an excessive thickness. However, because the inner space in the housing of the notebook computer is quite limited, it is difficult to reduce the thickness of the front edge of the housing.

Currently, improving the space utilization in the housing of a notebook computer involves either reducing the size of electronic components in the housing or re-arranging the layout of the electronic components so that they are packed together more closely in the housing. However, there are many different kinds of electronic components in a notebook computer, so that reducing the size of the electronic components requires broad knowledge in many fields of technology, as well as significant research and development capabilities. Accordingly, many in the industry are endeavoring to develop techniques that enable the electronic components in the housing of a notebook computer to be closely arranged.

### SUMMARY

In order to solve the problems of the prior art, the invention provides an improved electronic apparatus. The volume of a housing of the electronic apparatus can be reduced by obliquely and firmly fastening a circuit board in the housing. In order to obliquely fasten the circuit board in the housing of the electronic apparatus, a circuit board module of the invention is designed to provide two different fastening planes for fastening of the housing and the circuit board respectively. Furthermore, in order to firmly fasten the circuit board in the housing of the electronic apparatus, at least two supporting ribs are respectively disposed at an upper cover and a lower cover of the housing of the electronic apparatus, so that the circuit board can be clamped between the supporting ribs to be firmly fastened in the housing and thus maintain the oblique positioning relative to the housing. With the foregoing layout, the volume of the electronic apparatus can be reduced.

According to an embodiment of the invention, an electronic apparatus includes an upper cover, a lower cover, a circuit board, and a bracket. The upper cover includes a first boss. The lower cover includes a second boss. The bracket includes a first fixing plate and a second fixing plate that are connected to each other. The first fixing plate is clamped between the first boss and the second boss. The second fixing plate tilts at an angle relative to the first fixing plate and is fixed with the circuit board in a parallel manner.

In an embodiment of the invention, the electronic apparatus further includes a fastening member. The first boss has a threaded hole. The second boss has a channel. The first fixing plate has a through hole. The fastening member passes through the channel, the through hole, and then is fastened to the threaded hole.

In an embodiment of the invention, the first fixing plate includes at least one retaining portion for engaging the edge of the second boss.

In an embodiment of the invention, the first fixing plate includes at least one retaining portion for engaging the edge of the first boss.

In an embodiment of the invention, the circuit board has an opening, and the first boss or the second boss is passed through the opening in the circuit board.

In an embodiment of the invention, the upper cover further includes a first supporting rib. The lower cover further includes a second supporting rib. The circuit board is obliquely engaged between the first supporting rib and the second supporting rib.

In an embodiment of the invention, the material of the bracket includes metals. The second fixing plate is welded to the circuit board.

In an embodiment of the invention, the second fixing plate further includes a welding protrusion passing through the circuit board. The welding protrusion and the circuit board are welded to each other.

In an embodiment of the invention, the material of the bracket includes plastics. The second fixing plate is secured to the circuit board using a threaded engagement with the circuit board.

According to another embodiment of the invention, an electronic apparatus includes an upper cover, a lower cover, a circuit board, and a bracket. The upper cover includes a first boss. The lower cover includes a second boss and an oblique surface. The oblique surface tilts relative to the upper cover. The bracket includes a first fixing plate and a second fixing plate that are connected to each other. The first fixing plate is clamped between the first boss and the second boss. The second fixing plate tilts at an angle relative to the first fixing plate and is fixed with the circuit board in a parallel manner.

In an embodiment of the invention, the oblique surface is substantially parallel to the second fixing plate.

In an embodiment of the invention, the upper cover has a first inner surface. The lower cover has a second inner surface. The distance between the first inner surface and the second inner surface is larger than or equal to 2 cm.

In an embodiment of the invention, the upper cover and the lower cover have a minimum height in an assembled state. The minimum height is substantially twice the thickness of the circuit board.

An improved circuit board module is provided.

According to an embodiment of the invention, a circuit board module is capable of being assembled between an upper cover and a lower cover of an electronic apparatus. The upper cover includes a first boss. The first boss has a threaded hole. The lower cover includes a second boss. The second boss has a channel. A fastening member passes through the channel and is fastened to the threaded hole. The circuit board module includes a bracket and a circuit board. The bracket includes a first fixing plate and a second fixing plate that are connected to each other. The first fixing plate has a through hole. The first fixing plate is clamped between the first boss and the second boss. The fastening member passes through the through hole in the first fixing plate. The second fixing plate tilts at an angle relative to the first fixing plate. The circuit board is fixed with the second fixing plate in a parallel manner.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a perspective view of an electronic apparatus according to an embodiment of the invention; and

FIG. 2 is a sectional view of a housing in FIG. 1.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

An improved electronic apparatus is provided. The volume of a housing of the electronic apparatus can be reduced by obliquely and firmly fastening a circuit board in the housing. In order to obliquely fasten the circuit board in the housing of the electronic apparatus, a circuit board module of the invention is designed to provide two different fastening planes for fastening of the housing and the circuit board respectively. Furthermore, in order to firmly fasten the circuit board in the housing of the electronic apparatus, at least two supporting ribs are respectively disposed at an upper cover and a lower cover of the housing of the electronic apparatus, so that the circuit board can be clamped between the supporting ribs to be firmly fastened in the housing and thus maintain the oblique positioning relative to the housing. With the foregoing layout, the volume of the electronic apparatus can be reduced.

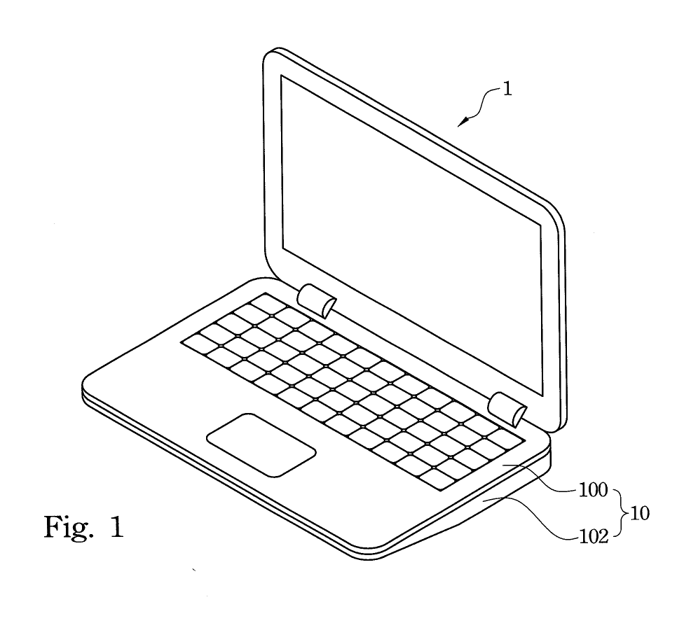

FIG. 1 is a perspective view of an electronic apparatus 1 according to an embodiment of the invention.

As shown in FIG. 1, the electronic apparatus 1 of the invention can be a portable computer device (e.g., a notebook computer, a tablet computer, etc.) or a consumer electronic product (e.g., a GPS, a PDA, a game console, etc.), but the invention is not limited in this regard. That is, the electronic apparatus 1 of the invention can be any portable electronic product. As long as there is a requirement to reduce the thickness of a certain portion of a portable electronic product, the concepts of the electronic apparatus 1 of the invention can be applied to effectively reduce the volume of the portable electronic product.

As shown in FIG. 1, the electronic apparatus 1 includes a housing 10. The housing 10 of the electronic apparatus 1 includes an upper cover 100 and a lower cover 102 that can be assembled to each other (by methods of engaging or fastening). Because the housing 10 of the electronic apparatus 1 has a specific layout therein, the ID (Industry Design) curve of the lower cover 102 of the electronic apparatus 1 can be thinned to a degree greater than with conventional configurations. That is, the lower cover 102 adjacent to the front side of the housing 10 has a thin ID curve, so the lower cover 102 and the upper cover 100 are partially oblique after assembly. The manner in which the volume of the lower cover 102 of the electronic apparatus 1 is reduced will be described in detail below.

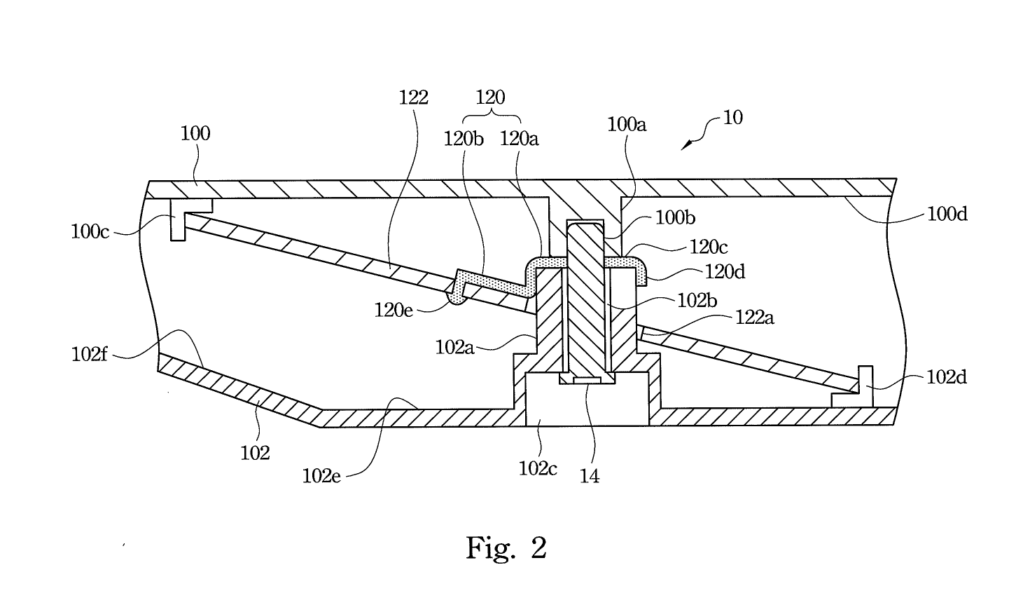

FIG. 2 is a sectional view of the housing 10 in FIG. 1.

As shown in FIG. 2, the upper cover 100 of the housing 10 includes a first boss 100a. The first boss 100a of the upper cover 100 has a threaded hole 100b. The lower cover 102 of the housing 10 includes a second boss 102a and an oblique surface 102f. The oblique surface 102f of the lower cover 102 tilts relative to the upper cover 100. The second boss 102a of the lower cover 102 has a channel 102b that communicates the inner space of the housing 10 with the space outside the housing 10. Therefore, by abutting the first boss 100a of the upper cover 10 to the second boss 102a of the lower cover 102 and aligning the threaded hole 100b of the first boss 100a to the channel 102b of the second boss 102a, a fastening member 14 (e.g., a screw) can pass through the channel 102b of the second boss 102a to fasten to the threaded hole 100b of the first boss 100a, so as to firmly assemble the upper cover 100 to the lower cover 102. Furthermore, in order to prevent the fastening member 14 from protruding from an outer surface of the lower cover 102, a counterbore hole 102c can be formed at an end of the channel 102b. The counterbore hole 102c extends inwardly from the outer surface of the lower cover 102, so as to obtain a smooth outer surface of the lower cover 102.

In an embodiment, a screw thread to which the fastening member 14 can be engaged can be formed on the inner wall of the channel 102b of the second boss 102a, so as to enhance the stability of fastening strength between the fastening member 14 and the lower cover 102.

As shown in FIG. 2, in order to achieve the purpose of reducing the volume of the lower cover 102 of the housing 10, an obliquely fastened circuit board module is disposed in the electronic apparatus 1, and the circuit board module includes a bracket 120 and a circuit board 122. The bracket 120 of the circuit board module includes a first fixing plate 120a and a second fixing plate 120b that are connected to each other. The first fixing plate 120a of the bracket 120 is clamped between the first boss 100a of the upper cover 100 and the second boss 102a of the second cover 102. The second fixing plate 120b of the bracket 120 tilts at an angle relative to the first fixing plate 120a. The circuit board 122 of the circuit board module is fixed with the second fixing plate 120b of the bracket 120 in a parallel manner. In the embodiment, the oblique surface 102f of the lower cover 102 is substantially parallel to the second fixing plate 120b of the bracket 120, but the invention is not limited in this regard. It can be seen that the first fixing plate 120a and the second fixing plate 120b of the bracket 120 of the circuit board module can provide two fixing planes that are not parallel to each other and are respectively fixed to the housing 10 and the circuit board 122, so as to achieve the purpose of obliquely fastening the circuit board 122 of the circuit board module in the housing 10.

In an embodiment, the angle between the first fixing plate 120a and the second fixing plate 120b of the bracket 120 can be 15 degrees, but the invention is not limited in this regard. That is, if a plane on which the upper surface of the first fixing plate 120a and a plane on which the upper surface of the second fixing plate 120b are extended until the planes intersect, the angle between the two planes is approximately 15 degrees in some embodiments. The angle between the first fixing plate 120a and the second fixing plate 120b of the bracket 120 can be adjusted according to the requirements of design (e.g., ID curve) or limitations of manufacture (e.g., space arrangement).

As shown in FIG. 2, in order to enhance the stability of the fixing strength between the bracket 120 and the housing 10, a through hole 120c can be formed in the first fixing plate 120a of the bracket 120. The size of the through hole 120c of the first fixing plate 120a is suitable to allow the fastening member 14 to pass therethrough. Therefore, by aligning two ends of the through hole 120c of the first fixing plate 120a to the threaded hole 100b of the first boss 100a and the channel 102b of the second boss 102a respectively, the fastening member 14 can be fastened to the threaded hole 100b of the first boss 100a after passing through the channel 102b of the second boss 102a and the through hole 120c of the first fixing plate 120a. With this configuration, not only does the fastening member 14 firmly assemble the upper cover 100 and the lower cover 102, but also, as a result of passing through the through hole 120c, the fastening member 14 provides the function of retaining (or positioning) the bracket 120 when the first fixing plate 120a is clamped between the first boss 100a and the second boss 102a.

As shown in FIG. 2, in order to enhance the stability of the fixing strength between the bracket 120 and the housing 10, the first fixing plate 120a of the bracket 120 can further include at least one retaining portion 120d. The retaining portion 120d of the first fixing plate 120a downwardly engages the edge of the second boss 102a so as to limit the horizontal movement of the bracket 120 relative to the second boss 102a. In another embodiment, the horizontal movement of the bracket 120 relative to the second boss 102a can also be limited by the retaining portion 120d of the first fixing plate 120a upwardly engaging the edge of the first boss 100a.

In another embodiment, the retaining portion 120d of the first fixing plate 120a can be formed in a sleeve-shaped configuration (not shown) and may entirely encase the edge of the second boss 102a or that of the first boss 100a, so as to enhance the stability of the fixing strength between the bracket 120 and the housing 10.

As shown in FIG. 2, because the first boss 100a of the upper cover 100 and the second boss 102a of the lower cover 102 obstruct the inner space of the housing 10, the circuit board 122 of the circuit board module can further have an opening 122a. The opening 122a of the circuit board 122 allows the first boss 100a of the upper cover 100 or the second boss 102a of the lower cover 102 to pass therethrough. Therefore, the first boss 100a of the upper cover 100 or the second boss 102a of the lower cover 102 does not prevent such oblique positioning of the circuit board 122 in the housing 10.

In another embodiment, two pairs of the first boss 100a and the second boss 102a are respectively located at two sides of the circuit board 122 and each pair uses a bracket 120 that is fixed to the circuit board 122 and the housing 10. In such an embodiment, the opening 122a can be omitted from the configuration of the circuit board 122 of the circuit board module.

As shown in FIG. 2, in order to enhance the stability of the fixing strength between the bracket 120 and the housing 10, the upper cover 100 of the housing 10 can further include a first supporting rib 100c, and the lower cover 102 can further include a second supporting rib 102d. Therefore, the circuit board 122 of the circuit board module can be obliquely and firmly engaged between the first supporting rib 100c of the upper cover 100 and the second supporting rib 102d of the lower cover 102. Furthermore, in order to prevent displacement between the circuit board 122 and the first supporting rib 100c of the upper cover 100 or the second supporting rib 102d of the lower cover 102, retaining designs such as positioning holes or troughs (not shown) can be formed on the circuit board 122 for the first supporting rib 100c and the second supporting rib 102d to pass through or engage with.

As shown in FIG. 2, the material of the bracket 120 can include metals. The second fixing plate 120b is welded to the circuit board 122 of the circuit board module. The second fixing plate 120b of the bracket 120 further includes a welding protrusion 120e. The welding protrusion 120e passes through the circuit board 122. The welding protrusion 120e is welded to the side of the circuit board 122 that faces away from the bracket 120.

In another embodiment, in order to save costs and assuming that the strength of the applied materials is acceptable, the material of the bracket 120 can include plastics. When made including a plastic material(s), the second fixing plate 120b can be secured to the circuit board 122 of the circuit board module using a threaded engagement therewith.

Furthermore, the upper cover 100 of the housing 10 has a first inner surface 100d, the lower cover 102 has a second inner surface 102e, and the distance between the first inner surface 100d and the second inner surface 102e is larger than or equal to 2 cm.

In an embodiment, the upper cover 100 and the lower cover 102 have a minimum height when assembled, and the minimum height is substantially twice the thickness of the circuit board 122.

According to the foregoing recitations of the embodiments of the invention, it can be seen that the volume of the housing of the electronic apparatus can be reduced by obliquely and firmly fastening the circuit board in the housing. In order to obliquely fasten the circuit board in the housing of the electronic apparatus, the circuit board module of the invention is designed to provide two different fastening planes for fastening of the housing and the circuit board respectively. Furthermore, in order to firmly fasten the circuit board in the housing of the electronic apparatus, at least two supporting ribs are respectively disposed at an upper cover and a lower cover of the housing of the electronic apparatus, so that the circuit board can be clamped between the supporting ribs to be firmly fastened in the housing and thus maintain the oblique positioning relative to the housing. With the foregoing layout, the volume of the electronic apparatus can be reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. An electronic apparatus comprising:
an upper cover comprising a first boss;
a lower cover comprising a second boss;
a circuit board; and
a bracket comprising a first fixing plate and a second fixing plate that are connected to each other, the first fixing plate being clamped between the first boss and the second boss, and the second fixing plate tilting at an angle relative to the first fixing plate and being fixed with the circuit board in a parallel manner.

2. The electronic apparatus of claim 1, further comprising a fastening member, the first boss having a threaded hole, the second boss having a channel, the first fixing plate having a through hole, the fastening member passing through the channel, the through hole, and then being fastened to the threaded hole.

3. The electronic apparatus of claim 1, wherein the first fixing plate comprises at least one retaining portion for engaging the edge of the second boss.

4. The electronic apparatus of claim 1, wherein the first fixing plate comprises at least one retaining portion for engaging the edge of the first boss.

5. The electronic apparatus of claim 1, wherein the circuit board has an opening, and the first boss or the second boss is passed through the opening in the circuit board.

6. The electronic apparatus of claim 1, wherein the upper cover further comprises a first supporting rib, the lower cover further comprises a second supporting rib, and the circuit board is obliquely engaged between the first supporting rib and the second supporting rib.

7. The electronic apparatus of claim 1, wherein the material of the bracket comprises metals, and the second fixing plate is welded to the circuit board.

8. The electronic apparatus of claim 7, wherein the second fixing plate further comprises a welding protrusion passing through the circuit board, and the welding protrusion and the circuit board are welded to each other.

9. The electronic apparatus of claim 1, wherein the material of the bracket comprises plastics, and the second fixing plate is secured to the circuit board using a threaded engagement with the circuit board.

10. An obliquely fastened circuit board module capable of being assembled between an upper cover and a lower cover of an electronic apparatus, the upper cover comprising a first boss, the first boss having a threaded hole, the lower cover comprising a second boss, the second boss having a channel, a fastening member passing through the channel to fasten to the threaded hole, the obliquely fastened circuit board module comprising:
a bracket comprising a first fixing plate and a second fixing plate that are connected to each other, the first fixing plate having a through hole, the first fixing plate being clamped between the first boss and the second boss, the fastening member passing through the through hole in the first fixing plate, the second fixing plate tilting at an angle relative to the first fixing plate; and
a circuit board fixed with the second fixing plate in a parallel manner.

11. The obliquely fastened circuit board module of claim 10, wherein the first fixing plate comprises at least one retaining portion for engaging the edge of the second boss.

12. The obliquely fastened circuit board module of claim 10, wherein the first fixing plate comprises at least one retaining portion for engaging the edge of the first boss.

13. The obliquely fastened circuit board module of claim 10, wherein the circuit board has an opening, and the first boss or the second boss is passed through the opening in the circuit board.

14. The obliquely fastened circuit board module of claim 10, wherein the material of the bracket comprises metals, and the second fixing plate is welded to the circuit board.

15. The obliquely fastened circuit board module of claim 14, wherein the second fixing plate further comprises a welding protrusion passing through the circuit board, and the welding protrusion and the circuit board are welded to each other.

16. The obliquely fastened circuit board module of claim 10, wherein the material of the bracket comprises plastics, and the second fixing plate is secured to the circuit board using a threaded engagement with the circuit board.

17. An electronic apparatus comprising:
an upper cover comprising a first boss;
a lower cover comprising a second boss and an oblique surface, wherein the oblique surface tilts relative to the upper cover;
a circuit board; and
a bracket comprising a first fixing plate and a second fixing plate that are connected to each other, the first fixing plate being clamped between the first boss and the second boss, and the second fixing plate tilting at an angle relative to the first fixing plate and being fixed with the circuit board in a parallel manner.

18. The electronic apparatus of claim 17, wherein the oblique surface is substantially parallel to the second fixing plate.

19. The electronic apparatus of claim 17, wherein the upper cover has a first inner surface, the lower cover has a second inner surface, and the distance between the first inner surface and the second inner surface is larger than or equal to 2 cm.

20. The electronic apparatus of claim 17, wherein the upper cover and the lower cover have a minimum height in an assembled state, and the minimum height is substantially twice the thickness of the circuit board.
